(19) United States
(12) Patent Application Publication
(10) Pub. No.: US 2020/0287109 A1
(43) Pub. Date: Sep. 10, 2020

(54) ELECTRONIC DEVICE

(71) Applicant: InnoLux Corporation, Miao-Li County (TW)

(72) Inventors: Chi-Liang CHANG, Miao-Li County (TW); Fang-Ho LIN, Miao-Li County (TW); Ya-Fen CHENG, Miao-Li County (TW); Chia-Hui LIN, Miao-Li County (TW); I-Chang LIANG, Miao-Li County (TW); Hsin-Cheng HUNG, Miao-Li County (TW)

(21) Appl. No.: 16/793,256

(22) Filed: Feb. 18, 2020

(30) Foreign Application Priority Data
Mar. 4, 2019 (CN) 201910159481.3

(51) Int. Cl. H01L 33/60; H01L 27/15; H01L 33/58

(52) U.S. Cl. CPC H01L 33/60; H01L 33/58; H01L 27/156

(57) ABSTRACT

An electronic device includes a substrate, a light-emitting element, and a spacing structure. The light-emitting element is disposed on the substrate. The spacing structure is disposed adjacent to the light-emitting element, and the spacing structure includes a first wall, a second wall, and a boundary portion. The first wall includes a first protrusion portion and extends in a first direction. The second wall includes a second protrusion portion and extends in a second direction, and the first direction is different from the second direction. The boundary portion is connected to the first protrusion portion and the second protrusion portion, and the height of the boundary portion is lower than the height of the first protrusion portion.

### CROSS REFERENCE TO RELATED APPLICATIONS

This application claims the benefit of Chinese Patent Application No. 201910159481.3, filed Mar. 4, 2019, the entirety of which is incorporated by reference herein.

### BACKGROUND

### Technical Field

Embodiments of the present disclosure relate to an electronic device, and in particular they relate to an electronic device including a spacing structure.

### Description of the Related Art

Some electronic devices may include light sources in accordance with actual design requirements. In the light source module of the electronic device, dark regions easily occur at the corners of the electronic device to decrease the brightness uniformity.

In these electronic devices, a diffuser plate is often used to pass light evenly. In order to support the diffuser plate, support pins are required between the light-emitting element and the diffuser plate. As the size of the electronic device increases, the weight of the diffuser plate increases. In order to enhance the effectiveness of light diffusion and mixing, and to support heavier weight in a large-sized electronic device, the gap between the light-emitting element and the diffuser plate may increase, and the number of support pins may also increase. However, such structural modification will increase the number of components and the thickness of the light source module, and increase the manufacturing time. It is contrary to the design trend of thinning the electronic device.

In addition, when local dimming is performed in the aforementioned structure, there are still problems such as large halation or uneven brightness.

### SUMMARY

In some embodiments of the present disclosure, a spacing structure (e.g., a grid structure) is disposed on the substrate of the electronic device, and the light-emitting element is disposed adjacent to the spacing structure. Thereby, the number of components of the electronic device may be reduced or good brightness uniformity may be achieved by adjusting the shape, height, wall thickness or other features of the spacing structure.

In accordance with some embodiments of the present disclosure, an electronic device is provided. The electronic device includes a substrate, a light-emitting element, and a spacing structure. The light-emitting element is disposed on the substrate. The spacing structure is disposed adjacent to the light-emitting element, and the spacing structure includes a first wall, a second wall, and a boundary portion. The first wall includes a first protrusion portion and extends in a first direction. The second wall includes a second protrusion portion and extends in a second direction, and the first direction is different from the second direction. The boundary portion is connected to the first protrusion portion and the second protrusion portion, and the height of the boundary portion is lower than the height of the first protrusion portion.

The following embodiments, in conjunction with the drawings, will provide a more detailed description.

### BRIEF DESCRIPTION OF THE DRAWINGS

Aspects of the embodiments of the present disclosure can be understood from the following detailed description when reading with the accompanying figures. It should be noted that, in accordance with the standard practice in the industry, various features are not drawn to scale. In fact, the dimensions of the various features may be arbitrarily increased or reduced for clarity of discussion.

FIG. 1 is a partial cross-sectional view illustrating an electronic device according to one embodiment of the present disclosure.

FIG. 2 is a partial three-dimensional view illustrating a spacing structure according to one embodiment of the present disclosure.

FIG. 3A is a partial side view illustrating the spacing structure according to one embodiment of the present disclosure.

FIG. 3B is a partial top view illustrating the spacing structure according to one embodiment of the present disclosure.

FIG. 4 is a partial three-dimensional view illustrating a spacing structure according to another embodiment of the present disclosure.

FIG. 5 is a partial side view illustrating the spacing structure according to another embodiment of the present disclosure.

FIG. 6 is a partial top view illustrating the spacing structure according to another embodiment of the present disclosure.

FIG. 7A is a partial top view illustrating an electronic device generally having a plurality of support pins associated with a diffuser plate.

FIG. 7B is a partial top view illustrating the electronic device including a spacing structure.

FIG. 8 is a diagram illustrating the brightness-position relationship obtained by optical simulation along line L1 shown in FIG. 7A, line L2 shown in FIG. 7B, and line L3 shown in FIG. 7B.

FIG. 9 is a partial three-dimensional view illustrating a spacing structure according to still another embodiment of the present disclosure.

FIG. 10A is a partial side view illustrating the spacing structure according to still another embodiment of the present disclosure.

FIG. 10B is a partial top view illustrating the spacing structure according to another embodiment of the present disclosure.

FIG. 11 is a partial cross-sectional view illustrating an electronic device according to one embodiment of the present disclosure.

FIG. 12A is a schematic view illustrating the structure of a rigid material according to one embodiment of the present disclosure.

FIG. 12B is a schematic view illustrating the structure of a rigid material according to another embodiment of the present disclosure.

FIG. 13A is a partial cross-sectional view illustrating an electronic device according to one embodiment of the present disclosure.

FIG. 13B is a partial cross-sectional view illustrating an electronic device according to another embodiment of the present disclosure.

FIG. 13C is a partial cross-sectional view illustrating an electronic device according to still another embodiment of the present disclosure.

FIG. 14 is a partial side view illustrating the spacing structure according to one embodiment of the present disclosure.

FIG. 15 is a partial top view illustrating an electronic device according to one embodiment of the present disclosure.

FIG. 16 is a partial cross-sectional view illustrating an electronic device according to the embodiment of the present disclosure.

FIG. 17A and FIG. 17B are partial top views respectively illustrating an electronic device and another electronic device.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first component is formed on a second component in the description that follows may include embodiments in which the first component is formed in direct contact with the second component, and may also include embodiments in which additional components may be disposed between the first component and second component, so that the first component and second component may not be in direct contact. In addition, the present disclosure may repeat reference numerals and/or letters in the various embodiments. This repetition is for the purpose of simplicity and clarity and does not in itself dictate a relationship between the various embodiments and/or configurations discussed.

Furthermore, spatially relative terms, such as “beneath,” “below,” “lower,” “on,” “above,” “upper” and the like, may be used herein to easily describe the spatial relationship between one component to other components as illustrated in the figures. In addition to the orientation depicted in the figures, the spatially relative terms are intended to encompass different orientations of the device in use or operation The spatially relative terms used herein may likewise be interpreted accordingly when the device may be otherwise oriented (e.g., rotated 90 degrees or at other orientations).

In the present disclosure, the terms “about,” “approximately” and “substantially” typically mean a range of +/−20% of the stated value, more typically a range of +/−10% of the stated value, more typically a range of +/−5% of the stated value, more typically a range of +/−3% of the stated value, more typically a range of +/−2% of the stated value, more typically a range of +/−1% of the stated value and even more typically a range of +/−0.5% of the stated value. The stated value of the present disclosure is an approximate value. That is, when there is no specific description of the terms “about,” “approximately” and “substantially”, the stated value still includes the meaning of “about,” “approximately” or “substantially”.

Some variations of the embodiments are described. Throughout various views and illustrative embodiments, like reference numbers are used to designate like elements. It should be understood that additional operations can be provided before, during, and after the method, and some of the operations described can be replaced or eliminated for other embodiments of the method.

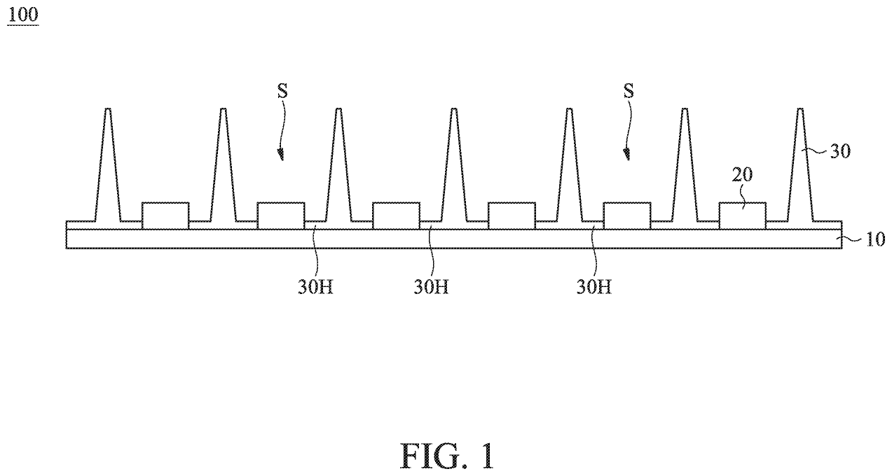

FIG. 1 is a partial cross-sectional view illustrating an electronic device 100 according to one embodiment of the present disclosure. In this embodiment, the electronic device 100 includes a substrate 10, a light-emitting element 20, and a spacing structure 30. As shown in FIG. 1, the light-emitting element 20 and the spacing structure 30 are disposed on the substrate 10, and the spacing structure 30 is disposed adjacent to the light-emitting element. In the embodiment shown in FIG. 1, the spacing structure 30 also includes a bottom plate 30H disposed to surround the light-emitting element 20, but the disclosure is not limited thereto. In some embodiments, the spacing structure 30 may not include the bottom plate 30H. It should be noted that only some components of the electronic device (for example, the electronic device 100) are drawn in the drawings of the present disclosure for the convenience of description, but the actual components, structural shapes and dimensions of the electronic device are not limited to the drawings.

In some embodiments, the substrate 10 may be a rigid or flexible substrate, and the substrate 10 may be a single-layer structure or a multi-layer structure. The material of the substrate 10 may, for example, include a printed circuit board (PCB), glass, quartz, sapphire or any other applicable rigid material, or polyimide (PI), polyethylene terephthalate (PET or PETE), poly(methyl methacrylate) (PMMA) or any other applicable flexible material, or a combination thereof. In some embodiments, the light-emitting element 20 may include light-emitting diodes (LEDs), but the present disclosure is not limited thereto. In other embodiments, the light-emitting element 20 may include lamps, bulbs, organic light-emitting diodes (OLEDs), quantum dots (QDs), quantum dot light-emitting diodes (QLEDs or QDLEDs), fluorescent materials, phosphor materials, micro light-emitting diode or mini light-emitting diodes, any other applicable luminescent material, or a combination thereof, but the present disclosure is not limited thereto.

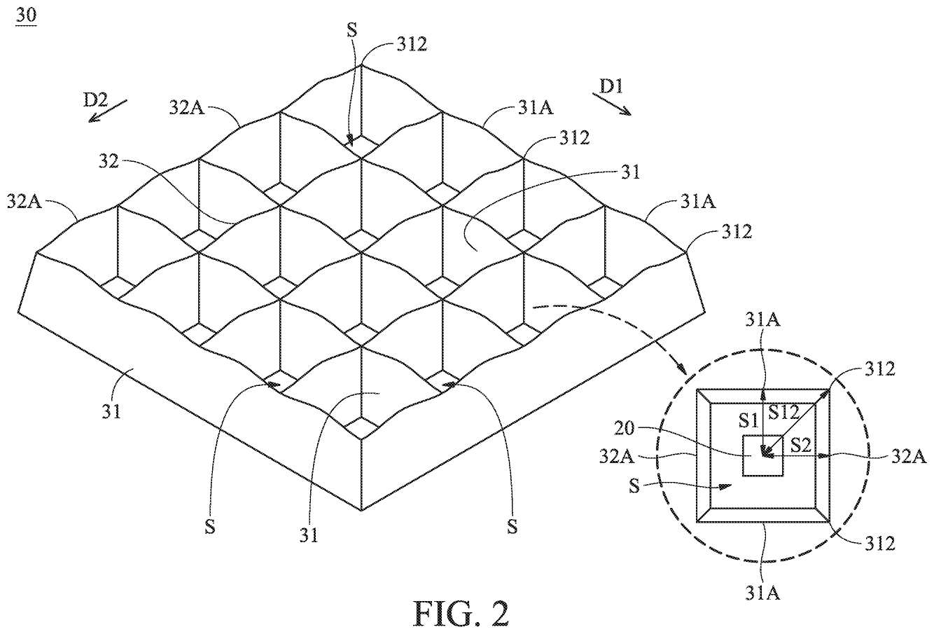

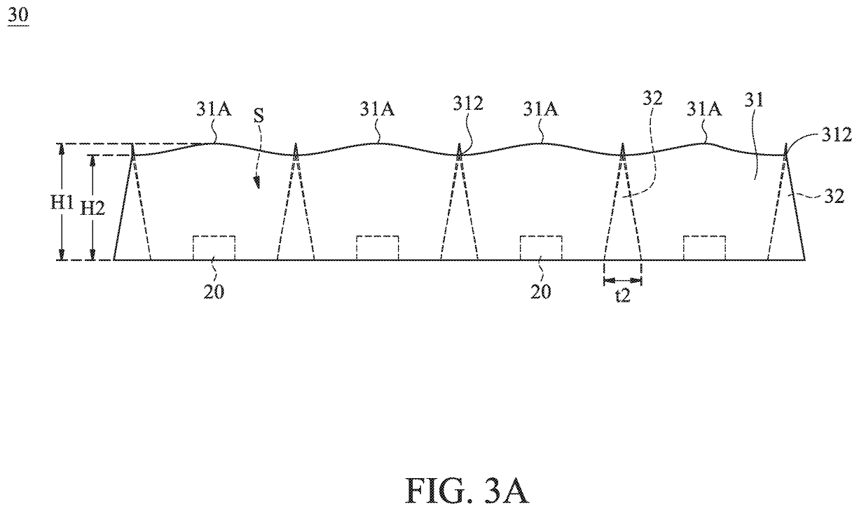

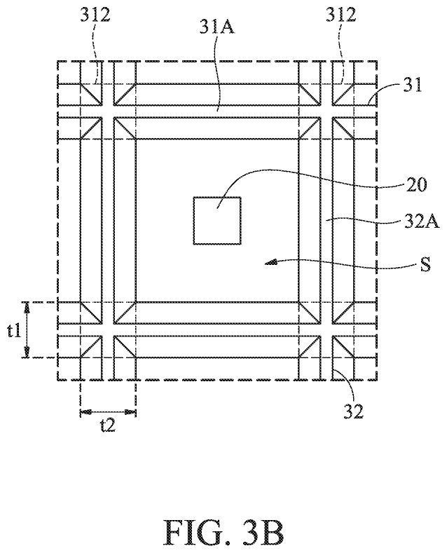

FIG. 2 is a partial three-dimensional view illustrating a spacing structure 30 according to one embodiment of the present disclosure. FIG. 3A is a partial side view illustrating the spacing structure 30 according to one embodiment of the present disclosure. It should be noted that, some components may be omitted in FIG. 1 to FIG. 3A in order to show the structure of the electronic device 100 of the embodiment of the present disclosure more clearly. For example, the bottom plate 30H of the spacing structure 30 shown in FIG. 1 does not appear in FIG. 3A. Further, it should be noted that, in the present disclosure, the light-emitting element 20 is also shown in the drawings associated with the spacing structure 30 (or the following 30′, 30-1, 30-2, 30-3) in order to clearly show the spatial relationship between the spacing structure 30 (or the following 30′, 30-1, 30-2, 30-3) and the light-emitting element 20. However, the light-emitting element 20 does not belong to a portion of the spacing structure 30 (or the following 30′, 30-1, 30-2, 30-3).

In some embodiments, the spacing structure 30 may be highly reflective, and the spacing structure 30 may include flexible or rigid materials, such as plastic, metal or the like, but the present disclosure is not limited thereto. Moreover, the color of the spacing structure 30 may be white or black, and the surface roughness of the spacing structure 30 may also be adjusted according to actual needs (for example, the need for reflectivity). Referring FIG. 1 to FIG. 3A, the spacing structure 30 includes a first wall 31 and a second wall 32. The first wall 31 extends in a first direction D1, and the second wall 32 extends in a second direction D2. In this embodiment, the first direction D1 is different from the second direction D2. For example, the first direction D1 is perpendicular to the second direction D2 in FIG. 2, but the present disclosure is not limited thereto.

As shown in FIG. 2, the spacing structure 30 includes a plurality of first wall 31 and a plurality of second walls 32 arranged to form a grid structure, and a plurality of light-emitting elements 20 may be respectively disposed in the accommodating space S formed by the plurality of first walls 31 and the plurality of second walls 32. In order to illustrate the main technical features of the present disclosure, the light-emitting element 20 is located at the center of the accommodating space S in a top view in some embodiments (e.g., the embodiments shown in FIG. 1 to FIG. 16) of the present disclosure, but the present disclosure is not limited thereto. In some embodiments, the light-emitting element 20 may not be located at the center of the accommodating space S in the top view.

As shown in FIG. 2 and FIG. 3A, in this embodiment, the spacing structure 30 includes the first wall 31, the second wall 32 and a boundary portion 312. The first wall 31 includes a first protrusion portion 31A and extends in a first direction D1. The second wall 32 includes a second protrusion portion 32A and extends in a second direction D2, wherein the first direction D1 is different from the second direction D2. The boundary portion 312 is connected to the first protrusion portion 31A and the second protrusion portion 32A, and the height H2 of the boundary portion 312 is lower than the height H1 of the first protrusion portion 31A. As shown in FIG. 3A, in the embodiment of the present disclosure, the height H2 of the boundary portion 312 is defined as the minimum height of the boundary portion 312 measured from the top surface of the substrate 10 in the normal direction of the substrate 10 (i.e., the direction perpendicular to the top surface of the substrate 10); the height H1 of the first protrusion portion 31A is defined as the maximum height of the first protrusion portion 31A measured from the top surface of the substrate 10 in the normal direction of the substrate 10.

Similarly, the height of the boundary portion 312 is lower than the height of the second protrusion portion 32A in this embodiment. The height of the second protrusion portion 32A is defined as the maximum height of the second protrusion portion 32A measured from the top surface of the substrate 10 in the normal direction of the substrate 10. In the embodiments of the present disclosure, the height of the first protrusion portion 31A and the height of the second protrusion portion 32A may be the same or different, which are not limited.

FIG. 3B is a partial top view illustrating the spacing structure 30 according to one embodiment of the present disclosure. As shown in FIG. 3B, the range of the boundary portion 312 may be defined by the thickness t1 of the bottom of the first wall 31 and the thickness t2 of the bottom of the second wall 32. For example, in this embodiment, the boundary portion 312 may be defined by the extension lines of the two edges at the bottom of the first wall 31 and the extension lines of the two edges at the bottom of the second wall 32 (e.g., the dashed box shown in FIG. 3B). The range that the first wall 31 deducts the boundary portion 312 may be defined as the range of the first protrusion portion 31A. Similarly, the range that the second wall 32 deducts the boundary portion 312 may be defined as the range of the second protrusion portion 32A. In this embodiment, the first wall 31 may have a plurality of first protrusion portions 31A, and one of the of first protrusion portions 31A is located between two boundary portions 312, but the present disclosure is not limited thereto.

Referring to the partial top view of the grid structure formed by the first walls 31 and the second walls 32 and circled by the dashed line in FIG. 2, in the accommodating space S formed by the first wall 31 and the second wall 32, the brightness measured in the accommodating space S decreases as the distance between the measuring point and the light-emitting element 20 increases. Therefore, when the light-emitting element 20 is disposed in an accommodating space S, since the distance S1 between the light-emitting element 20 and the first protrusion portion 31A is smaller than the distance S12 between the light-emitting element 20 and the boundary portion 312, the brightness at the boundary portion 312 and the vicinity is lower. In order to increase the brightness of the boundary portion 312 and the vicinity, the height H2 of the boundary portion 312 is designed to be lower than the height H1 of the first protrusion portion 31A, so that the light of the neighboring accommodation spaces S may transmit across the boundary portion 312, it may help to increase the brightness at the boundary portion 312 and the vicinity or increase the brightness uniformity in the accommodating space S.

Similarly, since the distance S2 between the light-emitting element 20 and the second protrusion portion 32A is smaller than the distance S12 between the light-emitting element 20 and the boundary portion 312, the height of the boundary portion 312 is designed to be lower than the height of the second protrusion portion 32A, it may help to increase the brightness at the boundary portion 312 or increase the brightness uniformity in the accommodating space S.

In this embodiment, the distance S1 between the light-emitting element 20 and the first protrusion portion 31A may be defined as the distance between the projection of the center of the light-emitting element 20 on the substrate 10 and the projection of the center of the first protrusion portion 31A on the substrate 10 in the top view; the distance S12 between the light-emitting element 20 and the boundary portion 312 may be defined as the distance between the projection of the center of the light-emitting element 20 on the substrate 10 and the projection of the center of the boundary portion 312 on the substrate 10 in the top view; the distance S2 between the light-emitting element 20 and the second protrusion portion 32A may be defined as the distance between the projection of the center of the light-emitting element 20 on the substrate 10 and the projection of the second protrusion portion 32A on the substrate 10 in the top view.

In other words, in this embodiment, by adjusting the height of the spacing structure 30 (the first wall 31 and the second wall 32), it is not necessary to add extra components of the electronic device 100 (e.g., a multi-layer diffusing plate), the light-emitting element 20 may mix light more uniformly in the accommodating space S formed by the first wall 31 and the second wall 32, improving the brightness uniformity of the electronic device 100, or reducing the thickness of the electronic device 100. Furthermore, the spacing structure 30 may be formed as one piece to shorten the manufacturing time.

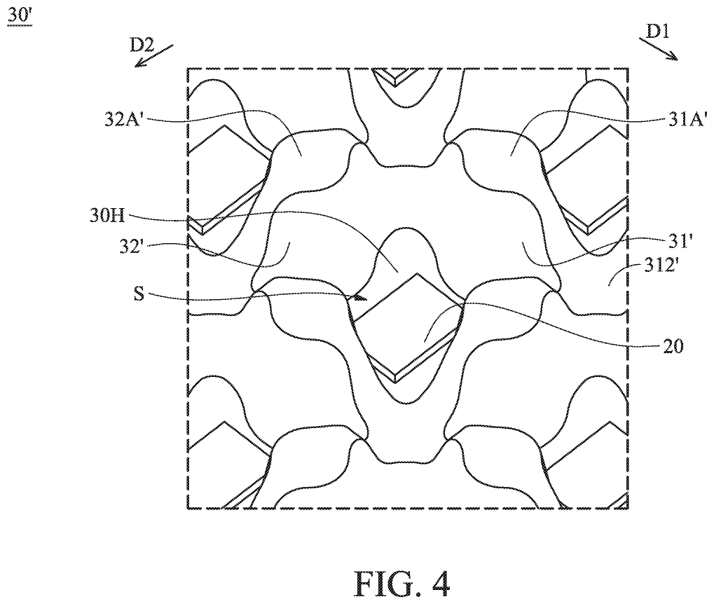

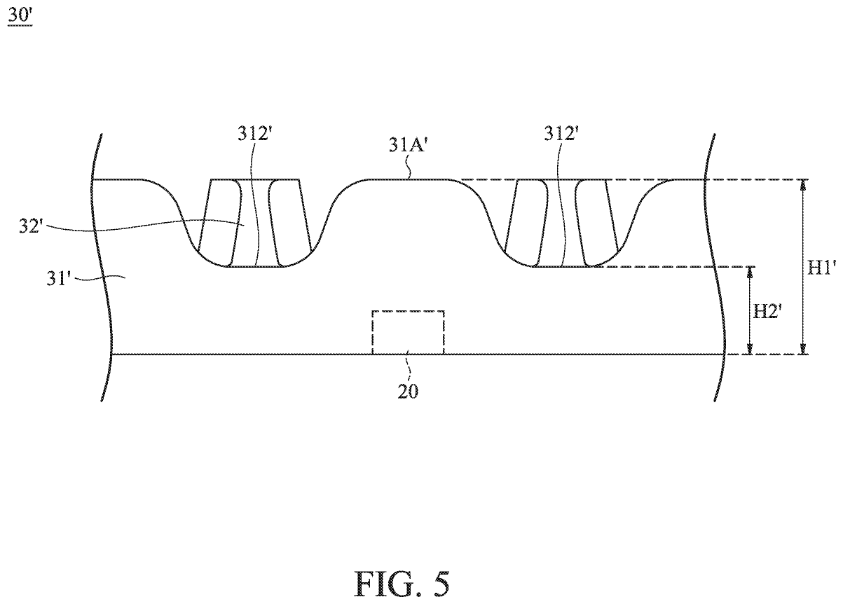

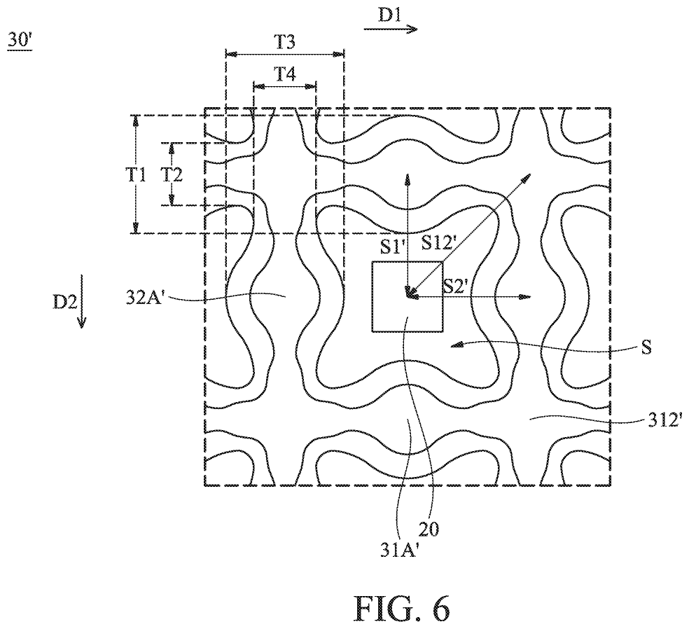

FIG. 4 is a partial three-dimensional view illustrating a spacing structure 30′ according to another embodiment of the present disclosure. FIG. 5 is a partial side view illustrating the spacing structure 30′ according to another embodiment of the present disclosure. FIG. 6 is a partial top view illustrating the spacing structure 30′ according to another embodiment of the present disclosure. It should be noted that some components may be omitted in FIG. 4 to FIG. 6 in order to more clearly show the structure of the spacing structure 30′ of the embodiment of the present disclosure.

The spacing structure 30′ shown in FIG. 4 to FIG. 6 may replace the spacing structure 30 shown in FIG. 1 to FIG. 3B to be provided in the electronic device 100 of the embodiment of the present disclosure.

As shown in FIG. 4, the spacing structure 30′ includes a plurality of first walls 31′ and a plurality of second walls 32′ arranged to form a grid structure, and a plurality of light-emitting elements 20 may be respectively disposed in the accommodating spaces S formed by the plurality of first walls 31′ and the plurality of second walls 32′. The spacing structure 30′ may further include a plurality of bottom plates 30H′ disposed in the bottoms of the accommodating spaces S, but the present disclosure is not limited thereto. In some embodiments, the spacing structure 30′ may not include the bottom plates 30H′. Moreover, the first walls 31′ extend in a first direction D1, and the second walls 32′ extend in a second direction D2. In this embodiment, the first direction D1 is different from the second direction D2. For example, the first direction D1 is perpendicular to the second direction D2 in FIG. 4 to FIG. 6, but the present disclosure is not limited thereto.

Referring to FIG. 4 and FIG. 5, in this embodiment, a first wall 31′ includes a first protrusion portion 31A′ and a second wall 32′ includes a second protrusion portion 32A′, and a boundary portion 312′ connects to the first protrusion portion 31A′ and the second protrusion portion 32A′. As shown in FIG. 5, the height H2′ of the boundary portion 312′ is lower than the height H1′ of the first protrusion portion 31A′. Similarly, the height of the boundary portion 312′ is lower than the height of the second protrusion portion 32A′. In this embodiment, the height of the first protrusion portion 31A′ and the height of the second protrusion portion 32A′ may be the same or different, which are not limited.

It should be noted that in this embodiment, the first wall 31′ and the second wall 32′ may have thickness variations as shown in FIG. 4 to FIG. 6. As shown in FIG. 6, the thickness of the wall may vary along the extending direction of the wall. For example, the thickness of the first protrusion portion 31A′ of the first wall 31′ along the first direction D1 may be varied between the maximum thickness T1 and the minimum thickness T2 (i.e., T2≤the thickness of the first wall 31′≤T1). Here, the thickness of the first protrusion portion 31A′ may be defined as the maximum thickness of the bottom of the first protrusion portion 31A′ measured in a direction perpendicular to the extending direction D1 of the first wall 31′ in the top view.

Similarly, the thickness of the second protrusion portion 32A′ of the second wall 32′ along the second direction D2 may be varied between the maximum thickness T3 and the minimum thickness T4 (i.e., T4≤the thickness of the second wall 32′≤T3). Here, the thickness of the second protrusion portion 32A′ may be defined as the maximum thickness of the bottom of the second protrusion portion 32A′ measured in a direction perpendicular to the extending direction D2 of the second wall 32′ in the top view. When the thickness of the wall varies along the extending direction of the wall, the range of the boundary portion 312′ is defined as the product of the minimum thickness T2 of the first wall 31′ and the minimum thickness T4 of the second wall 32′. That is, the thickness of the boundary portion 312′ is less than or equal to the thickness of the first protrusion portion 31A′ or the thickness of the second protrusion portion 32A′.

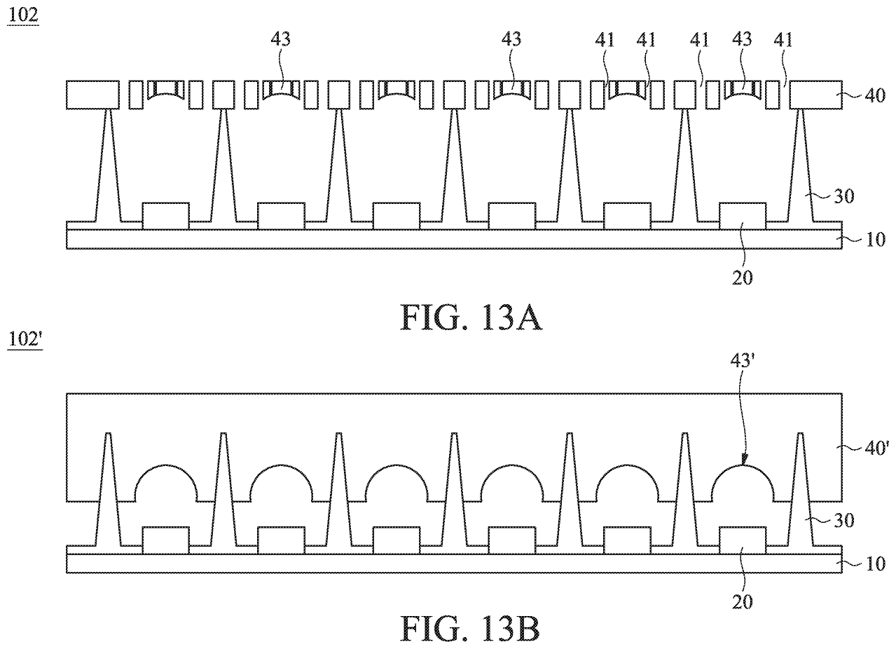

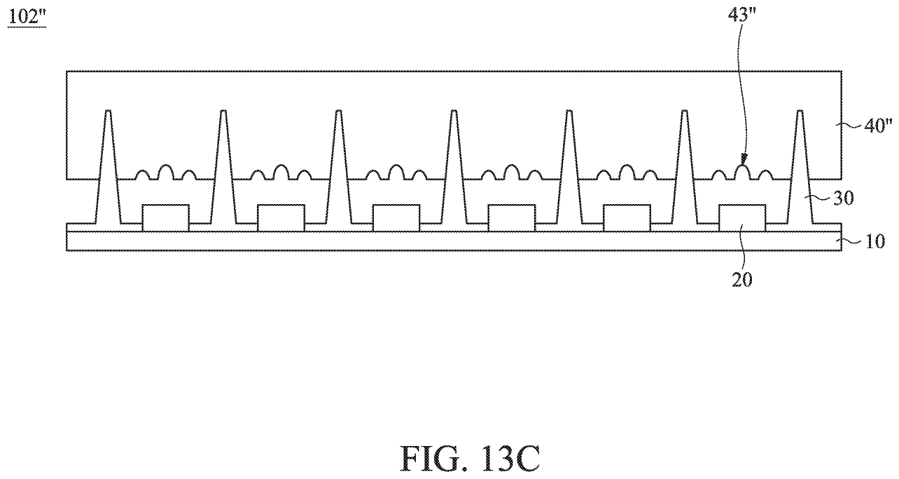

In some embodiments, other components may also be disposed on the spacing structure 30′ (e.g., the optical element 40 shown in following FIG. 13A). Since the height H2′ of the boundary portion 312′ is lower than the height H1′ of the first protrusion portion 31A′ (and the height of the second protrusion portion 32A′), the supporting stress of the spacing structure 30′ on the first wall 31′ may be concentrated on the first protrusion portion 31A′ (or the second protrusion portion 32A′). Therefore, in this embodiment, the maximum thickness T1 of the first protrusion portion 31A′ (or the maximum thickness T3 of the second protrusion portion 32A′) is designed to be greater than the thickness of the boundary portion 312′, so that the spacing structure 30′ may have better supporting ability.

Furthermore, in this embodiment, in addition to the fact that the thickness of the first wall 31′ and the second wall 32′ may vary along the extending direction of the wall, the first wall 31′ and the second wall 32′ may also have different thicknesses at different heights. For example, when the spacing structure 30′ shown in FIG. 4 to FIG. 6 replaces the spacing structure 30 shown in FIG. 1 to FIG. 3B and is disposed in the electronic device 100 of the present disclosure, the closer the first protrusion portion 31A′ of the first wall 31′ is to the substrate 10, the thicker the first protrusion portion 31A′ is. Similarly, the closer the second protrusion portion 32A′ of the second wall 32′ is to the substrate 10, the thicker the second protrusion portion 32A′ is, but the present disclosure is not limited thereto.

As shown in FIG. 6, when the light-emitting element 20 is disposed in the accommodating space S, since the distance S1′ between the light-emitting element 20 and the first protrusion portion 31A′ is smaller than the distance S12′ between the light-emitting element 20 and the boundary portion 312, the height H2′ of the boundary portion 312′ is designed to be smaller than the height H1′ of the first protrusion portion 31A′, it may help to increase the brightness at the boundary portion 312′ or increase the brightness uniformity in the accommodating space S. In this embodiment, the distance S1′ between the light-emitting element 20 and the first protrusion portion 31A′ may be defined as the distance between the projection of the center of the light-emitting element 20 on the substrate 10 and the projection of the center of the first protrusion portion 31A′ on the substrate 10 in the top view; the distance S12′ between the light-emitting element 20 and the boundary portion 312′ may be defined as the distance between the projection of the center of the light-emitting element 20 on the substrate 10 and the projection of the center of the boundary portion 312′ on the substrate 10 in the top view.

Similarly, since the distance S2′ between the light-emitting element 20 and the second protrusion portion 32A′ is smaller than the distance S12′ between the light-emitting element 20 and the boundary portion 312′, the height H2′ of the boundary portion 312′ is designed to be lower than the height of the second protrusion portion 32A′, it may help to increase the brightness at the boundary portion 312′ or increase the brightness uniformity in the accommodating space S. In this embodiment, the distance S2′ between the light-emitting element 20 and the second protrusion portion 32A′ may be defined as the distance between the projection of the center of the light-emitting element 20 on the substrate 10 and the projection of the center of the second protrusion portion 32A′ on the substrate 10 in the top view.

In the foregoing embodiments, the distance S1(S1′) between the light-emitting element 20 and the first protrusion portion 31A(31A′) being equal to the distance S2(S2′) between the light-emitting element 20 and the second protrusion portion 32A(32A′) is taken as an example, but the present disclosure is not limited thereto. In some embodiments, the distance S1(S1′) between the light-emitting element 20 and the first protrusion portion 31A(31A′) may be different from the distance S2(S2′) between the light-emitting element 20 and the second protrusion portion 32A(32A′).

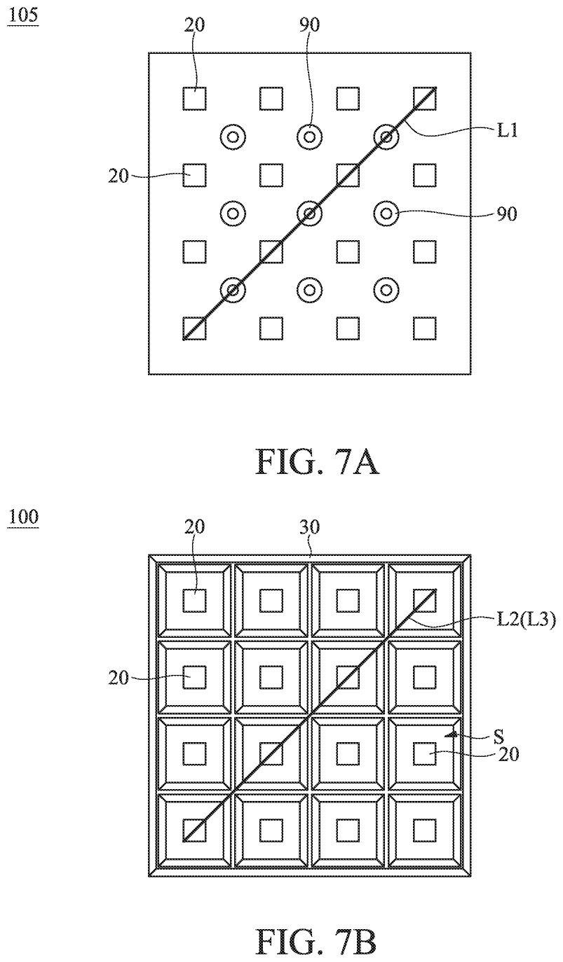

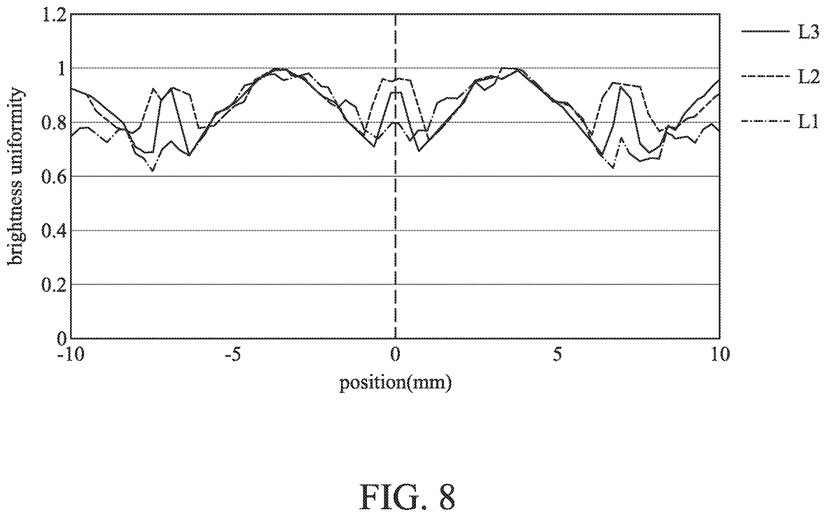

FIG. 7A is a partial top view illustrating an electronic device 105 generally having a plurality of support pins 90 associated with a diffuser plate. FIG. 7B is a partial top view illustrating the electronic device 100 including a spacing structure 30. FIG. 8 is a diagram illustrating the brightness-position relationship obtained by optical simulation along line L1 shown in FIG. 7A, line L2 shown in FIG. 7B, and line L3 shown in FIG. 7B. Line L2 is for the condition that the electronic device 100 includes the spacing structure 30 used in the embodiments of the present disclosure (i.e., the height of the boundary portion 312 is lower than the height of the first protrusion portion 31A and the second protrusion portion 32A), and line L3 is for the condition that the spacing structure has a uniform height (i.e., there is no height variation on the first wall 31 and the second wall 32, and the height of the first wall 31 and the height of the second wall 32 are the same).

In FIG. 8, the horizontal axis exhibits the position of each measuring point (the position of 0 mm represents the midpoint of the measuring path, for example, the midpoint of the measuring path is located at the boundary portion in FIG. 7B), and the vertical axis exhibits the brightness uniformity (i.e., the ratio of the brightness at each measuring point to the maximum brightness in the electronic device). As the simulation result shown in FIG. 8, in the electronic device 100 having the spacing structure 30 used in the embodiments of the present disclosure, the difference of brightness uniformity measured along line L2 is smaller than the other two. That is, the electronic device 100 including the spacing structure 30 of the embodiment of the present disclosure may achieve a better light mixing.

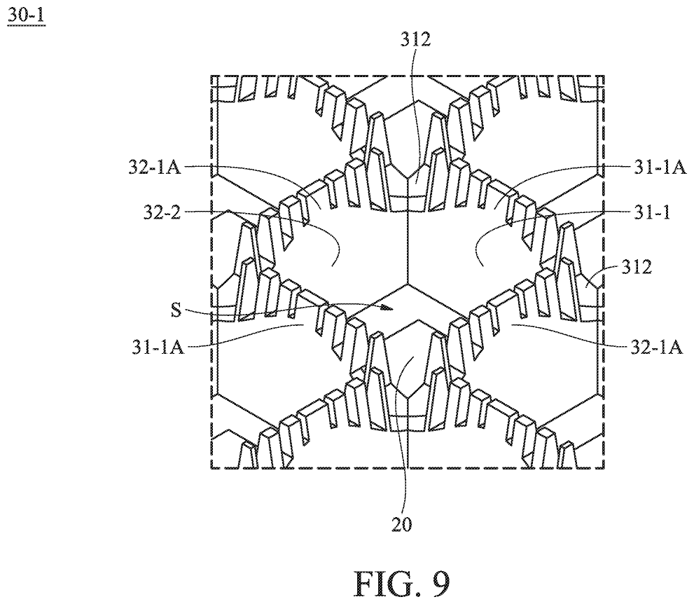

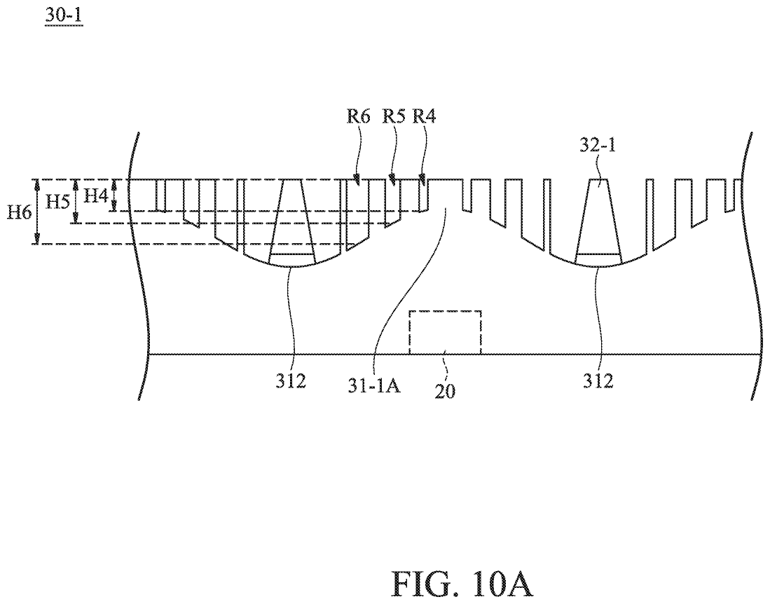

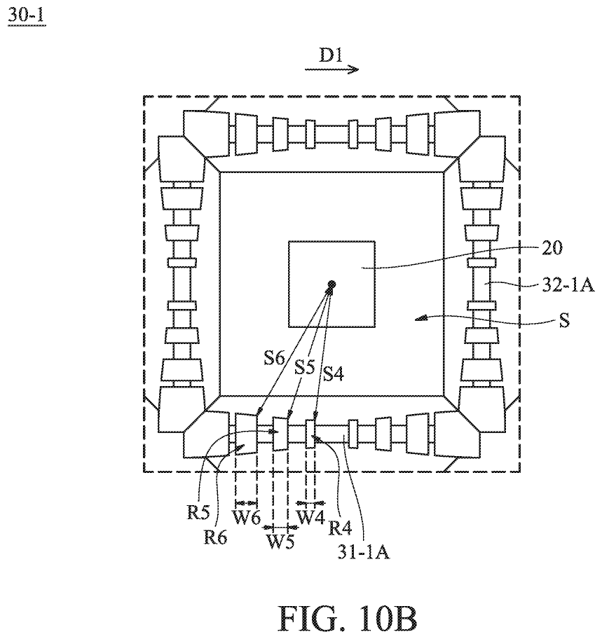

FIG. 9 is a partial three-dimensional view illustrating a spacing structure 30-1 according to still another embodiment of the present disclosure. FIG. 10A is a partial side view illustrating the spacing structure 30-1 according to still another embodiment of the present disclosure. FIG. 10B is a partial top view illustrating the spacing structure 30-1 according to another embodiment of the present disclosure. It should be noted that some components may be omitted in FIG. 9 to FIG. 10B in order to more clearly show the structure of the spacing structure 30-1 of the embodiment of the present disclosure.

The spacing structure 30-1 shown in FIG. 9 to FIG. 10B may replace the spacing structure 30 shown in FIG. 1 to FIG. 3B and may be disposed in the electronic device 100 of the embodiment of the present disclosure.

As shown in FIG. 9, the spacing structure 30-1 includes a plurality of first wall 31-1 and a plurality of second walls 32-1 arranged to form a grid structure, and a plurality of light-emitting elements 20 may be respectively disposed in the accommodating spaces S formed by the first walls 31-1 and the second walls 32-1.

Referring to FIG. 9 and FIG. 10A at the same time, in this embodiment, the first wall 31-1 includes a first protrusion portion 31-1A and the second wall 32-1 includes a second protrusion portion 32-1A, and the boundary portion 312 is connected to the first protrusion portion 31-1A and the second protrusion portion 32-1A. As shown in FIG. 10A, the height of the boundary portion 312 is lower than the height of the first protrusion portion 31-1A. Here, the height of the boundary portion 312 is defined as the minimum height of the boundary portion 312 measured from the top surface of the substrate 10 in the normal direction of the substrate 10 (i.e., the direction perpendicular to the top surface of the substrate 10). The height of the first protrusion portion 31-1A is defined as the maximum height of the first protrusion portion 31-1A measured from the top surface of the substrate 10 in the normal direction of the substrate 10.

Similarly, the height of the boundary portion 312 is lower than the height of the second protrusion portion 32-1A. The height of the second protrusion portion 32-1A is defined as the maximum height of the second protrusion portion 32-1A from the top surface of the substrate 10 in the normal direction of the substrate 10. In some embodiments, the height of the first protrusion portion 31-1A may be substantially equal to the height of the second protrusion portion 32-1A, but the present disclosure is not limited thereto.

As shown in FIG. 9 to FIG. 10B, in this embodiment, the first protrusion portion 31-1A includes a plurality of voids (R4, R5, R6). In this embodiment, the width of the void may vary depending on the distance between the void and the light-emitting element 20. Here, the distance between the void and the light-emitting element 20 may be defined as the shortest distance between the projection of the void on the substrate 10 and the projection of the center of the light-emitting element 20 on the substrate 10 in the top view, and the width of the void may be defined as the maximum width of the void measured in the extending direction of the wall. FIG. 10A and FIG. 10B show the voids R4, R5 and R6 between three sets of two adjacent protrusions 31C. As shown in FIG. 10B, the distance S4 between the void R4 and the light-emitting element 20 is smaller than the distance S5 between the void R5 and the light-emitting element 20, and the distance S5 between the void R5 and the light-emitting element 20 is smaller than the distance S6 between the void R6 and the light-emitting element 20; the width W4 of the void R4 is smaller than the width W5 of the void R5, and the width W5 of the void R5 is smaller than the width W6 of the void R6, but the present disclosure is not limited thereto.

Moreover, in this embodiment, the depth of each void of the first protrusion portion 31-1A may also be the same or different. In this embodiment, the depth of the void may be defined as the height difference between the bottom of the void and the top of first protrusion portion 31-1A in the normal direction of the top surface of the substrate 10. When the bottom of the void is not horizontal, the maximum depth of the void is referred to as the depth of the void. As shown in FIG. 10A, the voids R4, R5 and R6 have depths H4, H5 and H6, respectively, and the depth H4 is smaller than the depth H5, and the depth H5 is smaller than the depth H6, but the present disclosure is not limited thereto. In some embodiments, the depths of the some voids are the same, and in some other embodiments, the depths of all voids are the same.

Similarly, in this embodiment, the second protrusion portion 32-1A may include a plurality of voids. In this embodiment, the widths and depths of the voids of the second protrusion portion 32-1A are defined in the same manner as the voids R4, R5, and R6 of the first protrusion portion 31-1A, and will not be repeatedly described herein. It should be noted that in this embodiment, the widths and depths of the voids of the second protrusion portion 32-1A may be varied in the same manner as the voids R4, R5 and R6, but the present disclosure is not limited thereto.

In the embodiment shown in FIG. 9 to FIG. 10B, adjusting the widths and depths of the voids of the first protrusion portion 31-1A and the second protrusion portion 32-1A will help to improve the brightness uniformity in the accommodation space S.

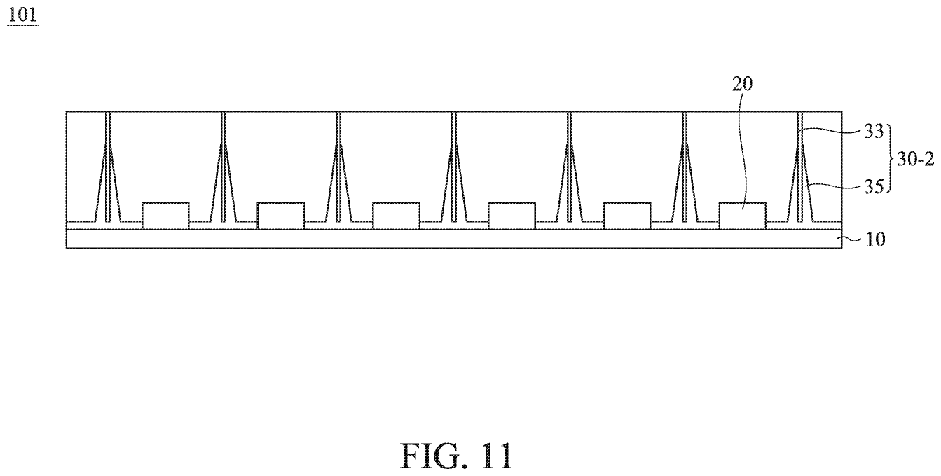

FIG. 11 is a partial cross-sectional view illustrating an electronic device 101 according to one embodiment of the present disclosure. In this embodiment, the electronic device 101 includes a substrate 10, a light-emitting element 20, and a spacing structure 30-2. As shown in FIG. 11, the light-emitting element 20 and the spacing structure 30-2 are disposed on the substrate 10, and the spacing structure 30-2 is disposed adjacent to the light-emitting element 20.

In this embodiment, the spacing structure 30-2 may include a rigid portion 33 and an elastic portion 35 which may cover a part of the outer surface of the rigid portion 33, but the present disclosure is not limited thereto. For example, the material of the rigid portion 33 may include a highly reflective metal sheet (e.g., an aluminum sheet, a stainless-steel sheet), a highly reflective organic material, or a translucent material. In some embodiments, the material of the rigid portion 33 may include a transparent material, such as at least one of glass, polycarbonate (PC), poly(methyl methacrylate) (PMMA), polystyrene (PS), and silicon, or a combination thereof.

Since the rigid portion 33 has better supporting ability, the supporting ability of the spacing structure 30-2 having multiple material combinations may be further improved as compared with the spacing structure completely made of the elastic material.

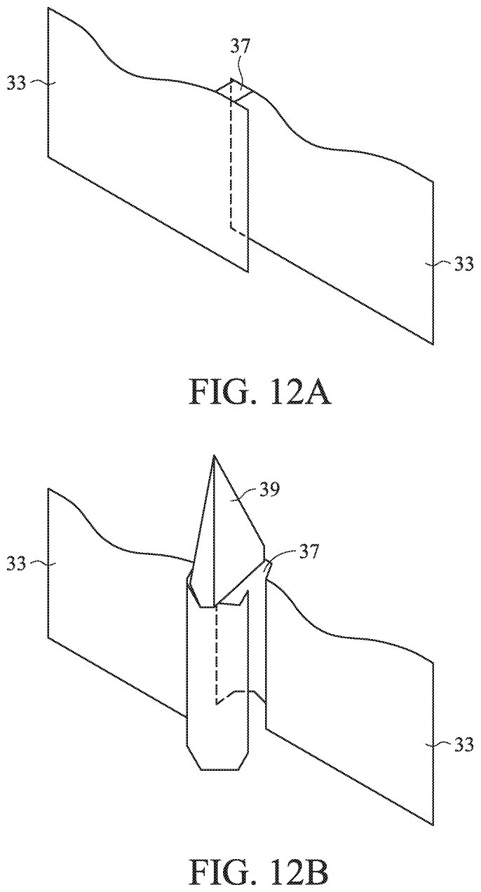

FIG. 12A is a schematic view illustrating the structure of a rigid material according to one embodiment of the present disclosure. Since the rigid material is not easily folded, in some embodiments, a connecting member 37 may be further disposed between the two rigid portions 33 in a manner as shown in FIG. 12A, so that the two rigid portions 33 may be connected to each other in a staggered manner. The connecting member 37 may have the same material as the rigid portion 33, or may be made of other suitable materials. Moreover, the rigid portion 33 and the connecting member 37 may be formed as one piece, and may also be formed and connected by techniques such as welding, adhesion, or the like. The connection of the connecting member 37 and the rigid portion 33 is not limited in the present disclosure.

FIG. 12B is a schematic view showing the structure of a rigid material according to another embodiment of the present disclosure. In the embodiment shown in FIG. 12B, a support pin 39 may be further disposed on the connecting member 37 to enhance the supporting ability and the light mixing of the spacing structure 30-2. It should be noted that the support pin 39 needs to be located at the first protrusion portion (or the second protrusion portion), and may have the same material as the rigid portion 33, or may be made of other suitable materials. Moreover, the support pin 39 is not limited to the shape shown in FIG. 12B, and may be adjusted depending on actual needs (e.g., size of the connecting member 37, top surface area, or the like).

FIG. 13A is a partial cross-sectional view illustrating an electronic device 102 according to one embodiment of the present disclosure. In this embodiment, the electronic device 102 includes a substrate 10, a light-emitting element 20, and a spacing structure 30. As shown in FIG. 13A, the light-emitting element 20 and the spacing structure 30 are disposed on the substrate 10, and the spacing structure 30 is disposed adjacent to the light-emitting element 20. It should be noted that the spacing structure 30 in the embodiment may also be replaced by the other spacing structures described above (e.g., the spacing structure 30′, the spacing structure 30-1, or the spacing structure 30-2), and will not be further described herein.

Furthermore, in this embodiment, the electronic device 102 further includes an optical element 40 disposed on the spacing structure 30, and the optical element 40 has the effect of changing the light path. For example, the surface of the optical element 40 is provided with prisms or other patterns that may change the light path, or particles that may refract or scatter light is added inside the optical element 40, but the present disclosure is not limited thereto. In some embodiments, the optical element 40 may be a peg board, that is, the optical element 40 may have at least one hole 41. In the embodiment shown in FIG. 13A, the optical element 40 may have a plurality of holes 41. The optical element 40 may be used to further enhance light uniformity.

In some embodiments, the optical element 40 may include at least one lens 43. The lens 43 may be a semi-convex lens or a convex lens. In some embodiments, the lens 43 includes transparent materials. For example, the material of the lens 43 may include glass, epoxy resin, silicone resin, polyurethane, any other applicable material, or a combination thereof. It should be noted that although the optical element 40 includes both the holes 41 and the lens 43 in the electronic device shown in FIG. 13A, but the present disclosure is not limited thereto. In some embodiments, the optical element 40 may include the holes 41, but not include the lens 43; in other embodiments, the optical element 40 may include lens 43, but not include the holes 41.

FIG. 13B is a partial cross-sectional view illustrating an electronic device 102′ according to another embodiment of the present disclosure. In this embodiment, the electronic device 102′ includes a substrate 10, a light-emitting element 20, and a spacing structure 30. As shown in FIG. 13B, the light-emitting element 20 and the spacing structure 30 are disposed on the substrate 10, and the spacing structure 30 is disposed adjacent to the light-emitting element 20. It should be noted that the spacing structure 30 in the embodiment may also be replaced by the other spacing structures described above (e.g., the spacing structure 30′, the spacing structure 30-1, or the spacing structure 30-2), and will not be further described herein.

Furthermore, in this embodiment, the electronic device 102′ further includes an optical element 40′ disposed on the spacing structure 30. In this embodiment, the optical element 40′ may include one of a translucent material or a transparent material (e.g., glass, polycarbonate (PC), poly(methyl methacrylate) (PMMA), polystyrene (PS), silicon), or a combination thereof. In some embodiments, the optical element 40′ may include a curved bottom surface 43′. The curved bottom surface 43′ may change the direction of the light. In addition, the space formed by the bottom surface 43′ may also be used to accommodate a semi-convex lens or a convex lens, but the present disclosure is not limited thereto. In some embodiments, the optical element 40′ may not include any lens.

FIG. 13C is a partial cross-sectional view illustrating an electronic device 102″ according to still another embodiment of the present disclosure. In this embodiment, the electronic device 102″ includes a substrate 10, a light-emitting element 20, and a spacing structure 30. As shown in FIG. 13C, the light-emitting element 20 and the spacing structure 30 are disposed on the substrate 10, and the spacing structure 30 is disposed adjacent to the light-emitting element 20. It should be noted that the spacing structure 30 in the embodiment may also be replaced by the other spacing structures described above (e.g., the spacing structure 30′, the spacing structure 30-1, or the spacing structure 30-2), and will not be further described herein.

Furthermore, in this embodiment, the electronic device 102″ further includes an optical element 40″ disposed on the spacing structure 30. Similarly, in this embodiment, the optical element 40″ may include one of a translucent material or a transparent material (e.g., glass, polycarbonate (PC), poly(methyl methacrylate) (PMMA), polystyrene (PS), silicon), or a combination thereof. In some embodiments, the surface 43″ of the optical element 40″ facing the light-emitting element 20 is rough or has a specific pattern. The surface 43″ that is rough or has a specific pattern may further enhance the uniformity of light emitted from the light-emitting element 20. In some embodiments, the space formed by the surface 43″ may also be used to accommodate a semi-convex lens or a convex lens, but the present disclosure is not limited thereto. In some embodiments, the optical element 40″ may not include any lens.

In the foregoing embodiments, the optical elements 40, 40′ or 40″ may also be integrated with the diffuser plate (i.e., formed as a single piece with the diffuser plate), thereby further enhancing the uniformity of light emitted by the light-emitting element 20. Furthermore, as shown in FIG. 13B and FIG. 13C, the optical element 40′ or 40″ may be disposed on the spacing structure 30 (or the spacing structure 30′, the spacing structure 30-1, the spacing structure 30-2) and embedded into the spacing structure 30 (or the spacing structure 30′, the spacing structure 30-1, the spacing structure 30-2), but the present disclosure is not limited thereto.

FIG. 14 is a partial side view illustrating the spacing structure 30-3 according to one embodiment of the present disclosure. In this embodiment, the spacing structure 30-3 may be a hollow rigid portion 33′. For example, the material of the hollow rigid portion 33′ may include a highly reflective metal sheet (e.g., an aluminum sheet, a stainless-steel sheet), a highly reflective organic material, or a translucent material. In some embodiments, the material of the hollow rigid portion 33′ may include a transparent material, such as at least one of glass, polycarbonate (PC), poly(methyl methacrylate) (PMMA), polystyrene (PS), silicon, or a combination thereof.

Since the hollow rigid portion 33′ reduces the usage of materials, the weight of the spacing structure 30-3 may be lighter.

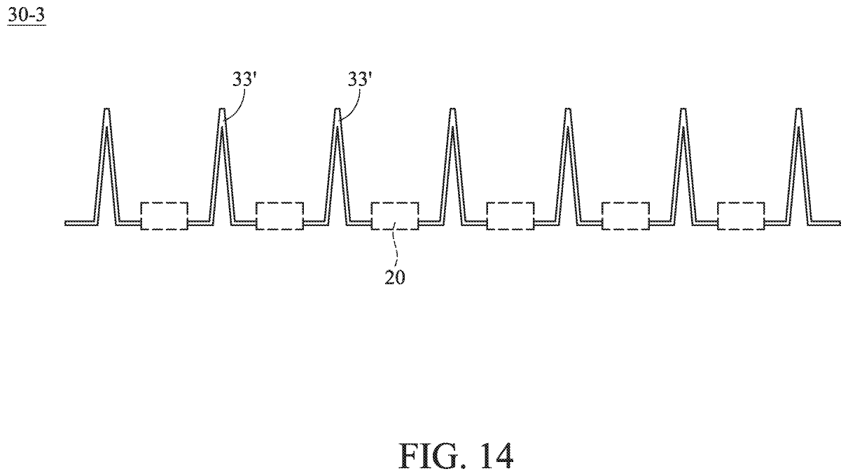

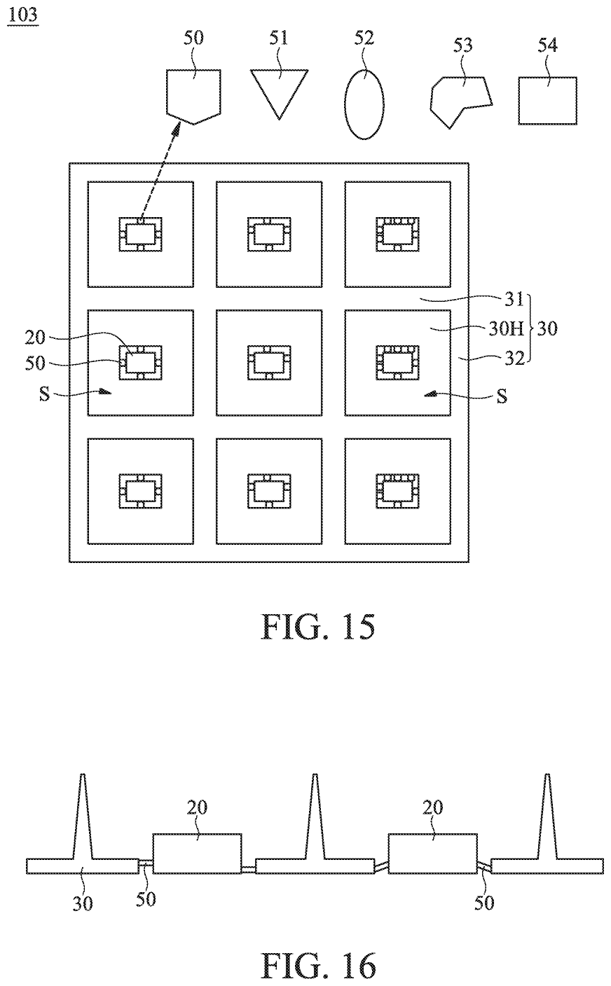

FIG. 15 is a partial top view illustrating an electronic device 103 according to one embodiment of the present disclosure. FIG. 16 is a partial cross-sectional view illustrating an electronic device 103 according to the embodiment of the present disclosure. In this embodiment, the spacing structure 30 further includes a plurality of bottom plates 30 and a plurality of position auxiliary blocks 50, and the position auxiliary blocks 50 are disposed adjacent to the light-emitting element 20. More specifically, the position auxiliary blocks 50 may be located in a gap between the light-emitting element 20 and the bottom plate 30H. It should be noted that the spacing structure 30 in the embodiment may be replaced by the other spacing structures described above (e.g., the spacing structure 30′, the spacing structure 30-1, or the spacing structure 30-2), and will not be further described herein.

As shown in FIG. 15 and FIG. 16, in this embodiment, the position auxiliary blocks 50 may be used to fix the position of the light-emitting element 20. The material of the position auxiliary block 50 may be the same as or different from the material of the first wall 31 and the second wall 32. Moreover, the embodiments of the present disclosure do not limit the shape of the position auxiliary block 50 and the number of position auxiliary block 50 around each of the light-emitting elements 20.

For example, the position auxiliary block 50 may also be the triangular position auxiliary block 51, elliptical position auxiliary block 52, polygonal position auxiliary block 53 or rectangular position auxiliary block 54 in FIG. 15, but the present disclosure is not limited thereto. In the embodiment of the present disclosure, the shape of each position auxiliary block 50 may be the same or different. In addition, the number of position auxiliary block 50 around the light-emitting elements 20 may be one or more, or there may be no position auxiliary block around the light-emitting elements 20. It should be noted that in the embodiment of the present disclosure, the number of position auxiliary block around each of the light-emitting elements 20 may be the same or different.

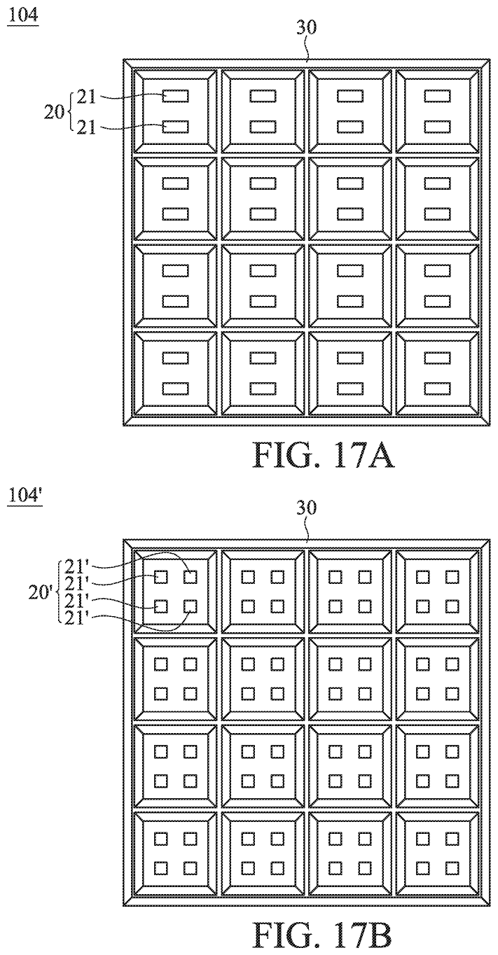

Although the light-emitting elements 20 are all illustrated as a single light source in the foregoing embodiments, the present disclosure is not limited thereto. FIG. 17A and FIG. 17B are partial top views respectively illustrating an electronic device 104 and an electronic device 104′. The light-emitting elements 20 and 20′ of the electronic device 104 and the electronic device 104′ respectively include a plurality of light sources 21 or 21′. In particular, in the electronic device 104 shown in FIG. 17A, the light-emitting element 20 includes two light sources 21; and in the electronic device 104′ shown in FIG. 17B, the light-emitting element 20′ includes four light sources 21′.

It should be noted that the number and arrangement of light sources are not limited in the embodiment of the present disclosure. In some embodiments, the light-emitting elements 20 in different accommodating spaces S of the same spacing structure 30 (30′, 30-1, 30-2, 30-3) may include different numbers of light sources 21 according to the design requirements. In addition, the type of light emitted by the light source 21 is not limited in the embodiment of the present disclosure. In some embodiments, the light-emitting element 20 may include light sources 21 that emit the same color. In some embodiments, the light-emitting element 20 may include light sources 21 that emit different colors. In some embodiments, the light-emitting element 20 may include light sources 21 that emit non-visible light, such as ultraviolet (UV) or infrared (IR) light. In addition, in some embodiments, other electronic components, such as sensors, may be included in the accommodating space S of the spacing structure 30 in addition to the light-emitting element 20.

Furthermore, when calculating the distance of the light-emitting element 20 from other components (e.g., the first wall 31 or the second wall 32), if the light-emitting element 20 includes only a single light source 21, then the position of the center of the light-emitting element 20 may be defined as the position of the center of the single light source 21 in the top view; if the light-emitting element 20 includes a plurality of light sources 21, the position of the center of the light-emitting elements 20 may be defined as the geometric center of the geometrical shape formed by the lines connecting the light sources 21 to each other in the top view.

According to the description of the foregoing embodiments, by adjusting the shape, height and the like of the spacing structure (including the first wall and the second wall), the brightness distribution in the accommodating space of the spacing structure may be more uniform without adding additional components of the electronic device (e.g., a multi-layer diffuser plate), thereby effectively reducing the thickness of the electronic device. Furthermore, the spacing structure may also be formed as a single piece with other components, to further shorten the manufacturing time and increase production efficiency.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various combinations, changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. An electronic device, comprising:
a substrate;
a light-emitting element disposed on the substrate; and
a spacing structure disposed adjacent to the light-emitting element, wherein the spacing structure comprises:
a first wall comprising a first protrusion portion and extending in a first direction;
a second wall comprising a second protrusion portion and extending in a second direction; and
a boundary portion connected to the first protrusion portion and the second protrusion portion;
wherein the first direction is different from the second direction, and a height of the boundary portion is lower than a height of the first protrusion portion.

2. The electronic device according to claim 1, wherein the first direction is perpendicular to the second direction.

3. The electronic device according to claim 1, wherein the height of the boundary portion is lower than a height of the second protrusion portion.

4. The electronic device according to claim 1, wherein a thickness of the first protrusion portion is greater than a thickness of the boundary portion, and a thickness of the second protrusion portion is greater than the thickness of the boundary portion.

5. The electronic device according to claim 1, wherein a distance between the light-emitting element and the first protrusion portion is smaller than a distance between the light-emitting element and the boundary portion in a top view.

6. The electronic device according to claim 1, wherein the first protrusion portion comprises a plurality of voids.

7. The electronic device according to claim 6, wherein depths of the voids are different from each other.

8. The electronic device according to claim 6, wherein widths of the voids are different from each other.

9. The electronic device according to claim 1, wherein the spacing structure comprises:
a rigid portion; and
an elastic portion coated on a part of an outer surface of the rigid portion.

10. The electronic device according to claim 9, wherein a material of the rigid portion comprises a highly reflective metal sheet, a highly reflective organic material, or a translucent material.

11. The electronic device according to claim 1, wherein the spacing structure further comprises at least one position auxiliary block disposed adjacent to the light-emitting element.

12. The electronic device according to claim 1, further comprising:
an optical element disposed on the spacing structure.

13. The electronic device according to claim 12, wherein the optical element comprises at least one hole or at least one lens.

14. The electronic device according to claim 12, wherein the optical element comprises a curved bottom surface.

15. The electronic device according to claim 12, wherein a surface of the optical element facing the light-emitting element is rough or has a specific pattern.

16. The electronic device according to claim 1, wherein the light-emitting element comprises a plurality of light sources.

17. The electronic device according to claim 1, wherein the spacing structure is a hollow rigid portion, and a material of the hollow rigid portion comprises a highly reflective metal sheet, a highly reflective organic material, or a translucent material.

18. An electronic device, comprising:
a substrate;
a plurality of first walls and a plurality of second walls disposed on the substrate, wherein the plurality of first walls and the plurality of second walls are arranged to form a grid structure; and
a plurality of light-emitting elements respectively disposed in accommodating spaces formed by the plurality of first walls and the plurality of second walls;
wherein one of the plurality of first walls comprises a first protrusion portion and a boundary portion, the boundary portion is connected to a corresponding one of the plurality of second walls, and a height of the boundary portion is lower than a height of the first protrusion portion.

19. The electronic device according to claim 18, wherein the corresponding one of the plurality of second walls comprises a second protrusion portion, and the height of the boundary portion is lower than a height of the second protrusion portion.

20. The electronic device according to claim 18, wherein a distance between one of the plurality of light-emitting elements disposed in one of the accommodating spaces and a first protrusion portion of one of the plurality of first walls corresponding to the one of the accommodating spaces is smaller than a distance between the one of the plurality of light-emitting elements disposed in the one of the accommodating spaces and a boundary portion of the one of the plurality of first walls corresponding to the one of the accommodating spaces.
